(19) United States
(12) Patent Application Publication
(10) Pub. No.: US 2025/0226283 A1
(43) Pub. Date: Jul. 10, 2025

(54) SEMICONDUCTOR PACKAGE AND METHOD OF MANUFACTURING THE SAME

(71) Applicant: SAMSUNG ELECTRONICS CO., LTD., SUWON-SI (KR)

(72) Inventors: WOOSEUP HWANG, Suwon-si (KR); JIHYE SHIM, Suwon-si (KR)

(21) Appl. No.: 18/909,151

(22) Filed: Oct. 8, 2024

(30) Foreign Application Priority Data
Jan. 4, 2024 (KR) 10-2024-0001680

(51) Int. Cl. H01L 23/373; H01L 23/367; H01L 23/538; H01L 25/065

(52) U.S. Cl. CPC H01L 23/373; H01L 23/3675; H01L 23/5386; H01L 25/0657; H01L 2225/06524

(57) ABSTRACT

A semiconductor package includes a first semiconductor structure including a first semiconductor substrate and a first penetration structure penetrating the first semiconductor substrate. A connection structure is disposed on the first semiconductor structure. A second semiconductor structure is on the connection structure. The second semiconductor structure includes a second semiconductor substrate and a second penetration structure penetrating the second semiconductor substrate. The connection structure includes a first heat conduction layer on the first semiconductor substrate. A first insulating layer is disposed on the first heat conduction layer. A second insulating layer is disposed on the first insulating layer. A second heat conduction layer is disposed on the second insulating layer. A heat dissipation member is interposed between the first insulating layer and the second insulating layer. The first heat conduction layer and the first insulating layer include different materials from each other.

### CROSS-REFERENCE TO RELATED APPLICATION

This application claims priority under 35 U.S.C. § 119 to Korean Patent Application No. 10-2024-0001680, filed on Jan. 4, 2024 in the Korean Intellectual Property Office, the disclosure of which is incorporated by reference in its entirety herein.

### 1. TECHNICAL FIELD

The present inventive concept relates to a semiconductor package and a method of manufacturing the same, and more specifically, relates to a semiconductor package in which a plurality of semiconductor chips are stacked on a substrate and a method of manufacturing the same.

### 2. DISCUSSION OF RELATED ART

The demand for high-performance, high-speed and compact electronic components are increasing along with the advancement of the electronics industry. Packaging technologies of mounting a plurality of semiconductor chips in a single package are being developed to provide such electronic components.

The demand for portable electronic devices is rapidly increasing in the market. Therefore, it is desired to have reduced sizes and weights of electronic components constituting the portable electronic devices. Research is being conducted to reduce a size and a weight of each component as well as packaging technologies of integrating several components in a single package. Multiple adhesive members may be used to bond multiple devices to each other. As the number of adhesive members increases, the occurrence of various problems increases.

### SUMMARY

An object of embodiments of the present inventive concept is to provide to a semiconductor package with increased heat dissipation characteristics and a method of manufacturing the same.

An object of embodiments of the present inventive concept is to provide to a semiconductor package with increased structural stability and a method of manufacturing the same.

An object of embodiments of the present inventive concept is to provide to a semiconductor package with less defects and a semiconductor package manufactured using the same.

The problem to be solved by embodiments of the present inventive concept is not limited to the problems mentioned above, and other problems not mentioned will be clearly understood by those skilled in the art from the description below.

According to an embodiment of the present inventive concept, a semiconductor package includes a first semiconductor structure including a first semiconductor substrate and a first penetration structure penetrating the first semiconductor substrate. A connection structure is disposed on the first semiconductor structure. A second semiconductor structure is on the connection structure. The second semiconductor structure includes a second semiconductor substrate and a second penetration structure penetrating the second semiconductor substrate. The connection structure includes a first heat conduction layer on the first semiconductor substrate. A first insulating layer is disposed on the first heat conduction layer. A second insulating layer is disposed on the first insulating layer. A second heat conduction layer is disposed on the second insulating layer. A heat dissipation member is interposed between the first insulating layer and the second insulating layer. The first heat conduction layer and the first insulating layer include different materials from each other.

According to an embodiment of the present inventive concept, a semiconductor package includes a first semiconductor structure including a first semiconductor substrate and a first penetration structure penetrating the first semiconductor substrate. A connection structure is disposed on the first semiconductor structure. A second semiconductor structure is disposed on the connection structure. The second semiconductor structure includes a second semiconductor substrate and a second penetration structure penetrating the second semiconductor substrate. A molding layer is disposed on the first semiconductor structure, the connecting structure, and the second penetration structure. The connection structure includes a first heat conduction layer disposed on the first semiconductor substrate. A first insulating layer is disposed on the first heat conduction layer. A second insulating layer is disposed on the first insulating layer. A second heat conduction layer is disposed on the second insulating layer. A heat dissipation member is interposed between the first insulating layer and the second insulating layer. An outer surface of the heat dissipation member protrudes towards the molding layer.

According to an embodiment of the present inventive concept, a semiconductor package includes a first semiconductor structure including a first semiconductor substrate and a first penetration structure penetrating the first semiconductor substrate. A connection structure is disposed on the first semiconductor structure. A second semiconductor structure is disposed on the connection structure. The second semiconductor structure includes a second semiconductor substrate and a second penetration structure penetrating the second semiconductor substrate. A molding layer is disposed on the first semiconductor structure, the connecting structure, and the second penetration structure. The connection structure includes a first heat conduction layer disposed on the first semiconductor substrate. A first insulating layer is disposed on the first heat conduction layer. A second insulating layer is disposed on the first insulating layer. A second heat conduction layer is disposed on the second insulating layer. A heat dissipation member is interposed between the first insulating layer and the second insulating layer. An outer surface of the heat dissipation member protrudes towards the molding layer. The heat dissipation member includes at least one material selected from epoxy, silicone, urethane, acrylate, aluminum oxide, boron nitride, zinc oxide, and aluminum nitride. A thermal conductivity of the first heat conduction layer is greater than a thermal conductivity of the first insulating layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view illustrating a semiconductor package according to an embodiment of the present inventive concept.

FIG. 2 is a cross-sectional view for explaining a semiconductor package according to an embodiment of the present inventive concept, and is an enlarged view corresponding to portion ‘Q’ of FIG. 1.

FIG. 3 is a cross-sectional view for explaining a semiconductor package according to an embodiment of the present inventive concept, and is an enlarged view corresponding to portion ‘Q’ of FIG. 1.

FIG. 4 is a cross-sectional view for explaining a semiconductor package according to an embodiment of the present inventive concept, and is an enlarged view corresponding to portion ‘Q’ of FIG. 1.

FIG. 5 is a cross-sectional view for explaining a semiconductor package according to an embodiment of the present inventive concept.

FIGS. 6 to 12 are cross-sectional views for explaining a method of manufacturing a semiconductor package according to embodiments of the present inventive concept.

### DETAILED DESCRIPTION OF EMBODIMENTS

A semiconductor package according to an embodiment of the present inventive concept will be described with reference to the drawings.

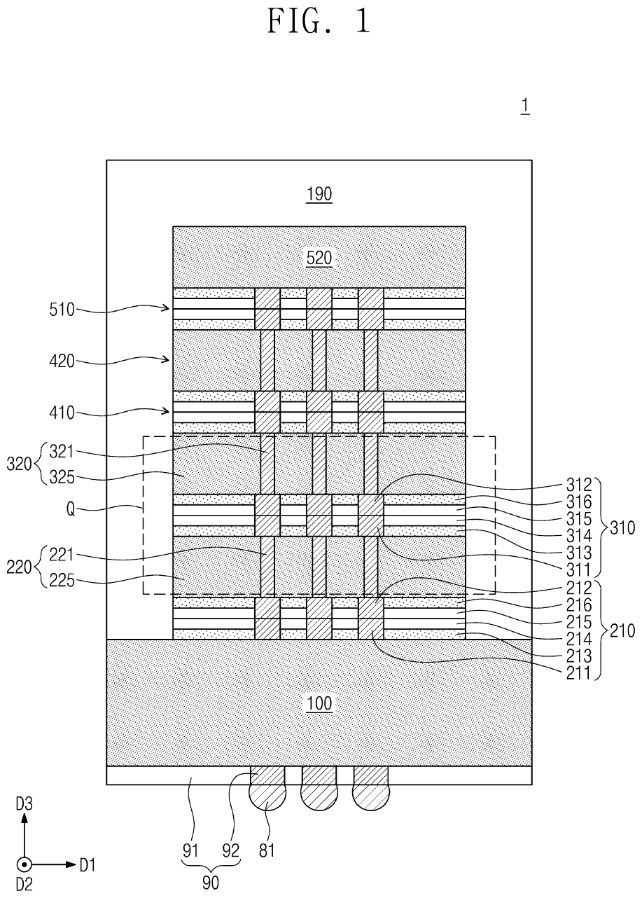

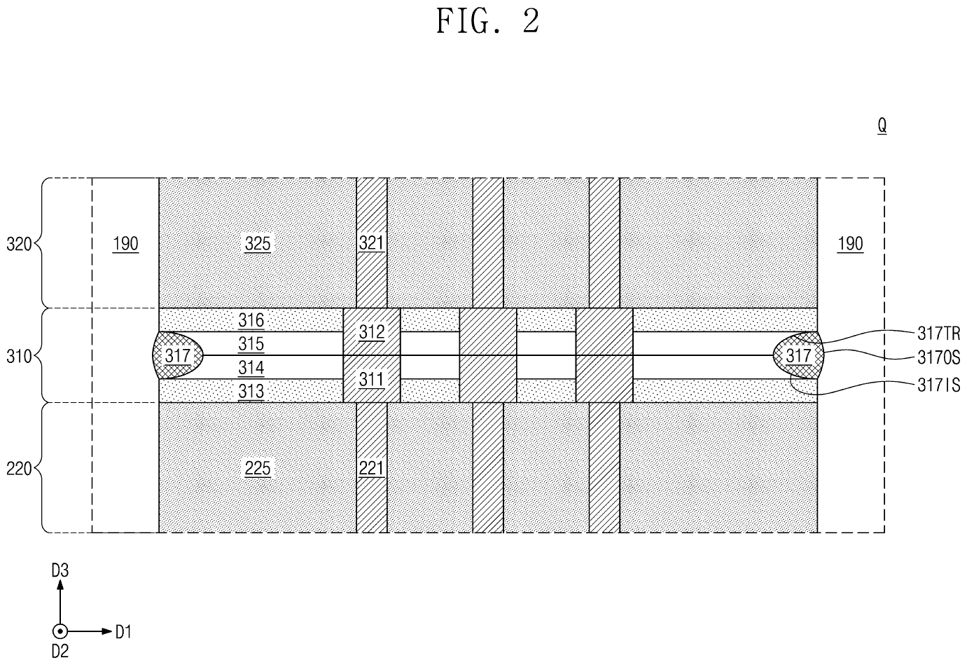

FIG. 1 is a cross-sectional view illustrating a semiconductor package according to an embodiment of the present inventive concept. FIG. 2 is a cross-sectional view for explaining a semiconductor package according to an embodiment of the present inventive concept, and is an enlarged view corresponding to portion ‘Q’ of FIG. 1. In FIG. 1, for convenience of explanation, some components are omitted or several components are merged and shown as one configuration.

A semiconductor package according to an embodiment of the present inventive concept may be a stacked package using a penetration structure. For example, semiconductor chips of the same type may be stacked on a base substrate (e.g., in a vertical direction, such as the third direction D3), and the semiconductor chips may be electrically connected to each other through penetration structures penetrating the semiconductor chips. The semiconductor chips may be connected to each other using pads thereof facing each other.

Referring to FIGS. 1 and 2, a semiconductor package 1 according to embodiments of the present inventive concept may have a shape of a plate extending along a plane defined in a first direction D1 and a second direction D2. The first direction D1 and the second direction D2 may intersect each other. For example, in an embodiment the first direction D1 and the second direction D2 may be perpendicular to each other. However, embodiments of the present inventive concept are not necessarily limited thereto and the first to third directions D1 to D3 may intersect each other at various different angles. The semiconductor package 1 according to an embodiment of the present inventive concept may include a plurality of semiconductor structures stacked in a third direction D3 orthogonal to a plane defined by the first direction D1 and the second direction D2.

The semiconductor package 1 according to an embodiment of the present inventive concept includes a solder ball 81, a solder layer 90, a base structure 100, a base connection structure 210 on the base structure 100 (e.g., disposed directly thereon in the third direction D3), a first semiconductor structure 220 on the base connection structure 210 (e.g., disposed directly thereon in the third direction D3), a first connection structure 310 on the first semiconductor structure 220 (e.g., disposed directly thereon in the third direction D3), a second semiconductor structure 320 on the first connection structure 310 (e.g., disposed directly thereon in the third direction D3), a second connection structures 410 on the semiconductor structure 320 (e.g., disposed directly thereon in the third direction D3), a third semiconductor structure 420 on the second connection structure 410 (e.g., disposed directly thereon in the third direction D3), a third connection structure 510 on the third semiconductor structure 420 (e.g., disposed directly thereon in the third direction D3), a fourth semiconductor structure 520 on the third connection structure 510 (e.g., disposed directly thereon in the third direction D3), and a molding layer 190 on (e.g., disposed directly thereon) the fourth semiconductor structure 520.

The solder ball 81 may be provided. In an embodiment, the solder ball 81 may contain a conductive material. The solder ball 81 may be electrically connected to the base structure 100, the first semiconductor structure 220, the second semiconductor structure 320, the third semiconductor structure 420, and the fourth semiconductor structure 520. In an embodiment, the solder ball 81 may electrically connect the base structure 100, the first semiconductor structure 220, the second semiconductor structure 320, the third semiconductor structure 420, and the fourth semiconductor structure 520 to an external device.

The solder layer 90 may be provided on (e.g., disposed directly thereon) the solder ball 81. In an embodiment, the solder layer 90 may include a solder insulating layer 91 and a solder pad 92. The solder insulating layer 91 may surround a side surface of the solder pad 92.

The solder insulating layer 91 may include an insulating material. In an embodiment, the solder insulating layer 91 may include, for example, at least one of silicon oxide (SiO), silicon nitride (SiN), and silicon oxynitride (SiON).

The solder pad 92 may include a conductive material. In an embodiment, the solder pad 92 may include, for example, one or more of copper (Cu), aluminum (Al), and/or nickel (Ni). The solder pad 92 may be electrically connected to the solder ball 81.

The base structure 100 may be provided on solder layer 90. The base structure 100 may include, for example, a base substrate and a base through-via.

In an embodiment, the base structure 100 may include an integrated circuit therein. For example, the base structure 100 may include a wafer level die made of a semiconductor such as silicon (Si). In some embodiments, the base structure 100 may include a substrate that does not include electronic devices such as transistors, and may include, for example, a printed circuit board (PCB).

The base connection structure 210 may be interposed between the base structure 100 and the first semiconductor structure 220 (e.g., in the third direction D3). In an embodiment, the base connection structure 210 may include a first base heat conduction layer 213, a first base insulating layer 214 on the first base heat conduction layer 213, and a second base insulating layer 215 on the first base insulating layer 214 (e.g., directly thereon in the third direction D3). The base connection structure 210 may further include a second base heat conduction layer 216 on the second base insulating layer 215 (e.g., directly thereon in the third direction D3).

In an embodiment, the base connection structure 210 may include a first base pad 211 penetrating the first base heat conduction layer 213 and a first base insulating layer 214. The base connection structure 210 may include a second base insulating layer 215 and a second base pad 212 penetrating a second base heat conduction layer 216.

The base connection structure 210 may have a structure similar to the first connection structure 310 described later. The base structure 100 and the first semiconductor structure 220 may be bonded to each other through the base connection structure 210. The base structure 100 and the first semiconductor structure 220 may be electrically connected through the base connection structure 210.

The first semiconductor structure 220 may be disposed on the base connection structure 210 (e.g., disposed directly thereon in the third direction D3). In an embodiment, the first semiconductor structure 220 may include a first semiconductor substrate 225 and a first penetration structure 221. A plurality of first penetration structures 221 may be provided. The first penetration structure 221 may penetrate the first semiconductor substrate 225.

The first semiconductor substrate 225, the base structure 100, and the solder ball 81 may be electrically connected to each other through the first penetration structure 221. The first penetration structure 221 may include a conductive material. In an embodiment, the first penetration structure 221 may include, for example, copper.

The first connection structure 310 may be disposed on the first semiconductor structure 220 (e.g., disposed directly thereon in the third direction D3). The first connection structure 310 may be interposed between the first semiconductor structure 220 and the second semiconductor structure 320 (e.g., in the third direction D3).

In an embodiment, the first connection structure 310 may include a first heat conduction layer 313, a first insulating layer 314 on the first heat conduction layer 313, a second insulating layer 315 on the first insulating layer 314, a second heat conduction layer 316 on the second insulating layer 315, and a heat dissipation member 317.

The first connection structure 310 may include a first connection pad 311 penetrating the first heat conduction layer 313 and the first insulating layer 314. The first connection structure 310 may include the second insulating layer 315 and a second connection pad 312 penetrating the second heat conduction layer 316. The first penetration structure 221, the first connection pad 311, the second connection pad 312, and the second penetration structure 321 may be electrically connected to each other.

In an embodiment, a side surface of the first connection pad 311 may be in direct contact with the first heat conduction layer 313 and the first insulating layer 314. The first connection pad 311 may include a conductive material. For example, in an embodiment the first connection pad 311 may include copper. A side surface of the second connection pad 312 may be in direct contact with the second insulating layer 315 and the second heat conduction layer 316. The second connection pad 312 may include a conductive material. For example, in an embodiment the second connection pad 312 may include copper.

The first semiconductor structure 220 and the second semiconductor structure 320 may be bonded to each other through the first connection structure 310. The first semiconductor structure 220 and the second semiconductor structure 320 may be electrically connected to each other through the first connection structure 310.

The first heat conduction layer 313 and the first insulating layer 314 may include different materials from each other. In an embodiment, the first heat conduction layer 313 may include aluminum nitride or boron nitride. The first insulating layer 314 may include silicon oxide. In an embodiment, the first heat conduction layer 313 may have a thickness in a range of about 0.1 um to about 3 um. In an embodiment, the thermal conductivity of the first heat conduction layer 313 may be greater than a thermal conductivity of the first insulating layer 314.

The second semiconductor structure 320 may be disposed on the first connection structure 310 (e.g., disposed directly thereon in the third direction D3). In an embodiment, the second semiconductor structure 320 may include a second semiconductor substrate 325 and a second penetration structure 321. A plurality of second penetration structures 321 may be provided. The second penetration structure 321 may penetrate the second semiconductor substrate 325.

The second semiconductor substrate 325 may be electrically connected to the first connection structure 310 through the second penetration structure 321.

A second connection structure 410 may be disposed on the second semiconductor structure 320 (e.g., disposed directly thereon in the third direction D3). The second connection structure 410 may have a similar structure to the first connection structure 310.

The third semiconductor structure 420 may be disposed on the second connection structure 410 (e.g., disposed directly thereon in the third direction D3). The third semiconductor structure 420 may have a similar structure to the first semiconductor structure 220.

The third connection structure 510 may be disposed on the third semiconductor structure 420 (e.g., disposed directly thereon in the third direction D3). The third connection structure 510 may have a similar structure to the first connection structure 310.

The fourth semiconductor structure 520 may be disposed on the third connection structure 510 (e.g., disposed directly thereon in the third direction D3). The fourth semiconductor structure 520 may be similar to the first semiconductor structure 220 except for a configuration corresponding to the first penetration structure 221. For example, the fourth semiconductor structure 520 may not include a penetration structure, such as the first penetration structure 221.

The molding layer 190 may be disposed on (e.g., disposed directly thereon) the base structure 100. The molding layer 190 may be arranged to surround the base connection structure 210, the first semiconductor structure 220, the first connection structure 310, the second semiconductor structure 320, the second connection structure 410, and the third semiconductor structure 420, the third connection structure 510, and the fourth semiconductor structure 520. The molding layer 190 may include an insulating material. For example, in an embodiment the molding layer 190 may include epoxy molding compound (EMC).

Referring to FIG. 2, portion ‘Q’ of FIG. 1 is shown in a more enlarged form. The first connection structure 310 and the second semiconductor structure 320 may be sequentially disposed on the first semiconductor structure 220 (e.g., in the third direction D3).

The first connection pad 311 of the first connection structure 310 may be disposed on the first penetration structure 221 of the first semiconductor structure 200 (e.g., disposed directly thereon in the third direction D3). The first penetration structure 221 may be in direct contact with the first connection pad 311.

In an embodiment, the first connection structure 310 may include a heat dissipation member 317 interposed between the first insulating layer 314 and the second insulating layer 315. In an embodiment, the heat dissipation member 317 may be disposed in an intervening trench 317TR formed by etching the first insulating layer 314 and the second insulating layer 315. The heat dissipation member 317 may be formed on one side surface and the other side surface opposite to each other of the first insulating layer 314 and the second insulating layer 315.

In an embodiment, the heat dissipation member 317 may include at least one material selected from epoxy, silicone, urethane, acrylates, aluminum oxide, boron nitride, zinc oxide and aluminum nitride.

A surface in which the heat dissipation member 317 is in direct contact with the molding layer 190 may be defined as an outer surface 317OS of the heat dissipation member 317. A surface in which the heat dissipation member 317 is in direct contact with the first and second insulating layers 314 and 315 may be defined as an inner surface 317IS of the heat dissipation member 317.

In an embodiment, the outer surface 317OS of the heat dissipation member 317 may include a curved surface. The inner surface 317IS of the heat dissipation member 317 may include a curved surface. In an embodiment, a curvature of the outer surface 317OS may be less than a curvature of the inner surface 317IS. The curvature of the inner surface 317IS may be greater than the curvature of the outer surface 317OS. The outer surface 317OS of the heat dissipation member 317 may protrude towards the molding layer 190 and be in direct contact therewith.

Lateral heat dissipation of heat generated from the semiconductor package 1 may be further increased by the heat dissipation member 317.

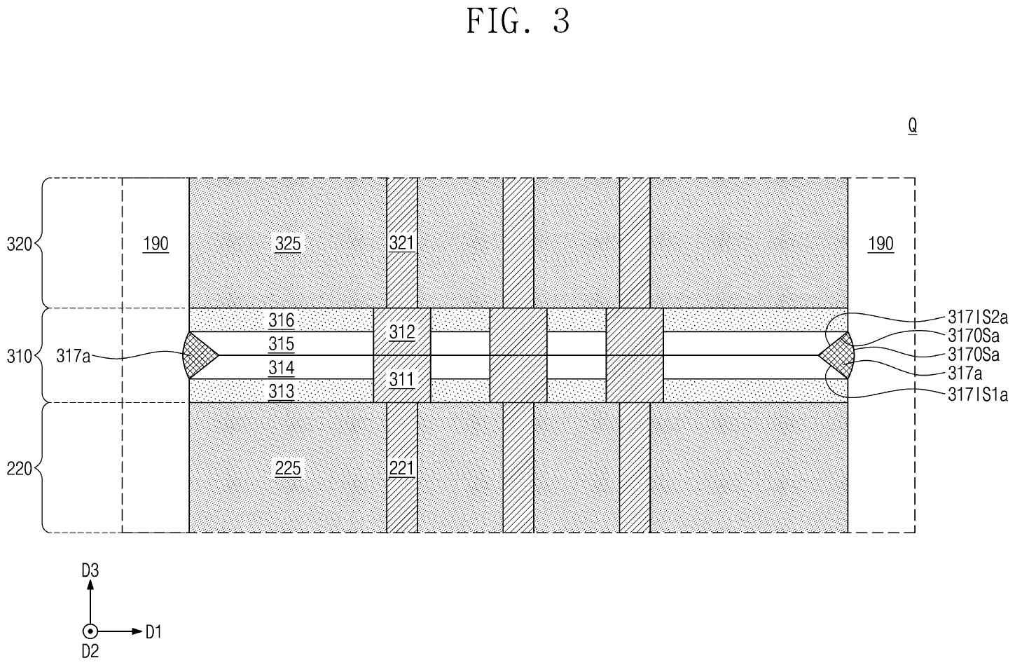

FIG. 3 is a cross-sectional view for explaining a semiconductor package according to an embodiment of the present inventive concept, and is an enlarged view corresponding to portion ‘Q’ of FIG. 1. To simplify the explanation, a repeated description of elements that overlap with the above-mentioned elements may be omitted.

Referring to FIG. 3, a first semiconductor structure 220, a first connection structure 310 on the first semiconductor structure 220, and a second semiconductor structure 320 on the first connection structure 310 may be provided. A molding layer 190 may be arranged to surround side surfaces of the first semiconductor structure 220, the first connection structure 310, and the second semiconductor structure 320.

The first connection structure 310 may include a heat dissipation member 317a interposed between the first insulating layer 314 and the second insulating layer 315. In an embodiment, the heat dissipation member 317a may be disposed in an intervening trench 317TRa formed by etching the first insulating layer 314 and the second insulating layer 315. The heat dissipation member 317a may be formed on one side surface and the other side surface opposite to each other of the first insulating layer 314 and the second insulating layer 315.

A surface in which the heat dissipation member 317a is in direct contact with the molding layer 190 may be defined as an outer surface 3170Sa of the heat dissipation member 317a. A surface in which the heat dissipation member 317a is in direct contact with the first insulating layer 314 may be defined as a first inner surface 317IS1a. A surface in which the heat dissipation member 317a is in direct contact with the second insulating layer 315 may be defined as a second inner surface 317IS2a.

The outer surface 3170Sa may include a curved surface. The first inner surface 317IS1a and the second inner surface 317IS2a may include an inclined surface. The outer surface 317OSa may protrude towards the molding layer 190 and be in direct contact therewith.

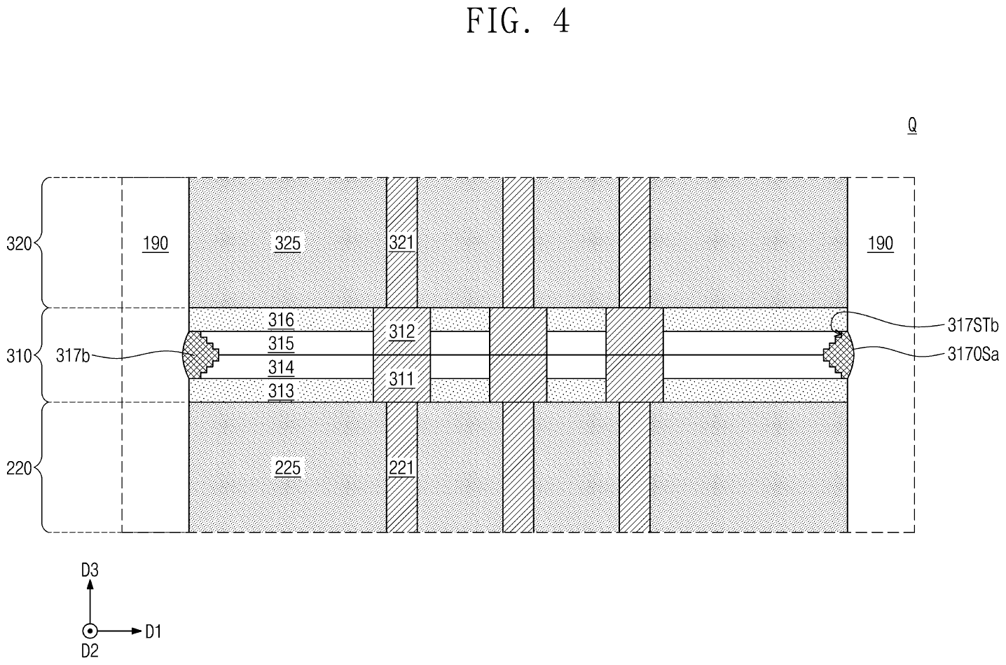

FIG. 4 is a cross-sectional view for explaining a semiconductor package according to an embodiment of the present inventive concept, and is an enlarged view corresponding to portion ‘Q’ of FIG. 1. To simplify the explanation, a repeated description of elements that overlap with the above-mentioned elements may be omitted.

Referring to FIG. 4, a first semiconductor structure 220, a first connection structure 310 on the first semiconductor structure 220, and a second semiconductor structure 320 on the first connection structure 310 may be provided. A molding layer 190 may be arranged to surround side surfaces of the first semiconductor structure 220, the first connection structure 310, and the second semiconductor structure 320.

In an embodiment, the first connection structure 310 may include a heat dissipation member 317b interposed between the first insulating layer 314 and the second insulating layer 315. In an embodiment, the heat dissipation member 317b may be disposed in an intervening trench 317TRb formed by etching the first insulating layer 314 and the second insulating layer 315. The heat dissipation member 317b may be formed on one side surface and the other side surface opposite to each other of the first insulating layer 314 and the second insulating layer 315.

A surface in which the heat dissipation member 317b is in direct contact with the molding layer 190 may be defined as an outer surface 3170Sb of the heat dissipation member 317b. The outer surface 3170Sb may include a curved surface. The outer surface 3170Sb may protrude towards the molding layer 190 and be in direct contact therewith.

The heat dissipation member 317b may include a step portion 317STb at a portion in direct contact with the first insulating layer 314 and the second insulating layer 315. In an embodiment, the step portion 317STb may have a staircase shape.

The heat dissipation member 317b may be in direct contact with the first insulating layer 314 in a step shape. The heat dissipation member 317b may be in direct contact with the second insulating layer 315 in a step shape.

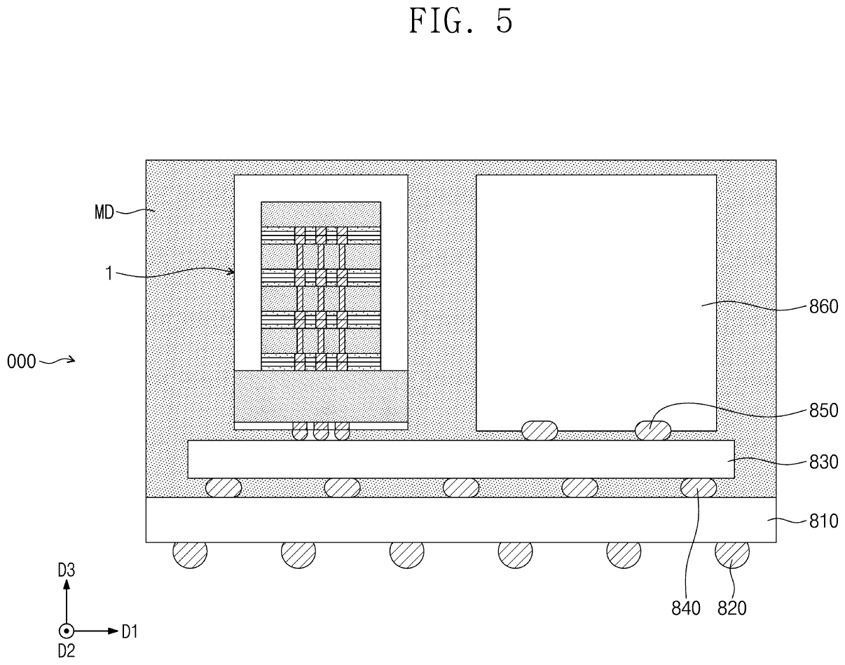

FIG. 5 is a cross-sectional view for explaining a semiconductor package according to an embodiment of the present inventive concept.

Referring to FIG. 5, a semiconductor package may include a package substrate 810. First terminals 820 electrically connected to the package substrate 810 may be disposed on a lower surface of the package substrate 810. In an embodiment, a semiconductor package may be mounted on an external device (e.g., a main board) through the first terminals 820.

An interposer 830 may be disposed on the package substrate 810. Second terminals 840 may be configured to electrically connect the package substrate 810 and the interposer 830 to each other. The second terminals 840 may be disposed between the package substrate 810 and the interposer 830 (e.g., in the third direction D3).

A processor chip 860 may be disposed on the interposer 830. For example, in an embodiment the processor chip 860 may be a graphics processing unit (GPU) or a central processing unit (CPU). Third terminals 850 may be configured to electrically connect the processor chip 860 and the interposer 830 to each other. The third terminals 850 may be disposed between the processor chip 860 and the interposer 830 (e.g., in the third direction D3).

The semiconductor package 1 of FIG. 1 may be disposed on the interposer 830. The semiconductor package 1 may be spaced apart from the processor chip 860 in the first direction D1. Solder balls that electrically connect the semiconductor package 1 and the interposer 830 to each other may be disposed between the semiconductor package 1 and the interposer 830 (e.g., in the third direction D3).

A molding layer MD surrounding the interposer 830, the processor chip 860, and the semiconductor package 1 may be disposed on the package substrate 810.

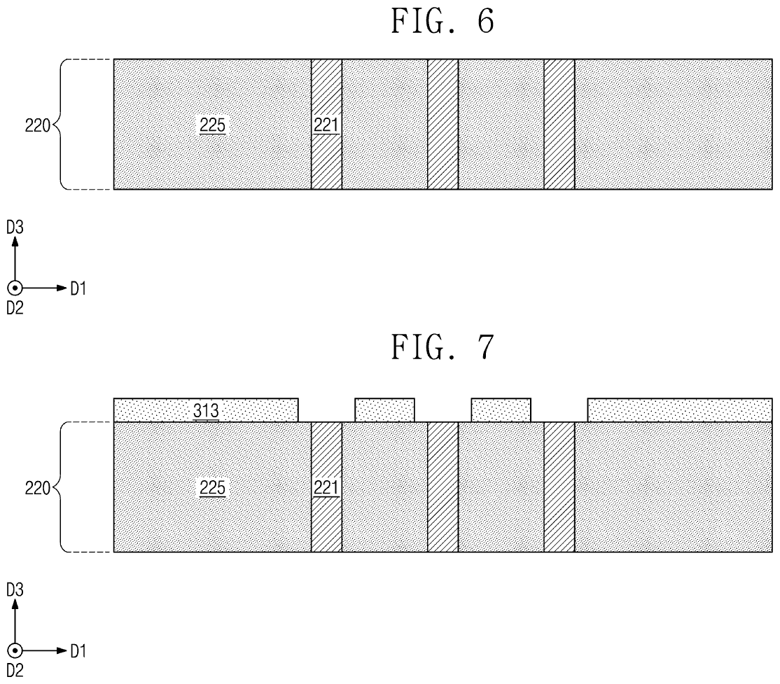

FIGS. 6 to 12 are cross-sectional views for explaining a method of manufacturing a semiconductor package according to embodiments of the present inventive concept.

Referring to FIG. 6, a first semiconductor structure 220 including a first semiconductor substrate 225 and a first penetration structure 221 may be provided. The first penetration structure 221 may be arranged to penetrate the first semiconductor substrate 225.

Referring to FIG. 7, a first heat conduction layer 313 may be formed on (e.g., formed directly thereon) the first semiconductor structure 220. In an embodiment, the forming of the first heat conduction layer 313 may include forming a material with high thermal conductivity through an etch mask. The forming of the first heat conduction layer 313 may include, for example, chemically depositing aluminum nitride on the first semiconductor structure 220 using an etch mask. The first heat conduction layer 313 may be formed excluding a space where a first connection pad 311 is to be formed. The space where the first connection pad 311 will be formed may be exposed. An upper surface of the first penetration structure 221 and a portion of an upper surface of the first semiconductor substrate 225 may be exposed.

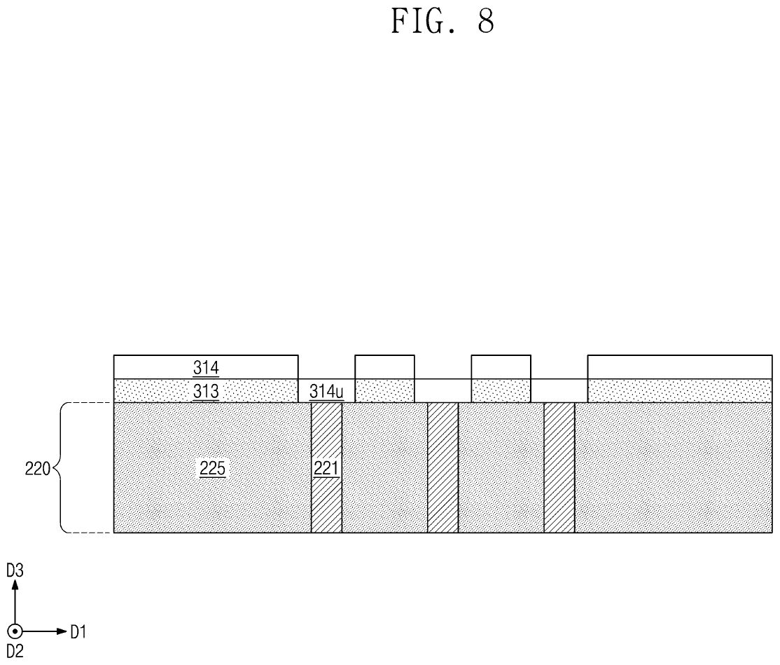

Referring to FIG. 8, a first insulating layer 314 may be formed on the first heat conduction layer 313 (e.g., formed directly thereon in the third direction D3). The forming of the first insulating layer 314 may include forming the first insulating layer 314 on the first heat conduction layer 313, and forming the first lower insulating layer 314u to cover the previously exposed upper surface of the first penetration structure 221 and the portion of the upper surface of the first semiconductor substrate 225. In an embodiment, the forming of the first insulating layer 314 may include, for example, forming the upper surface of the first heat conduction layer 313 with oxide while filling the space where the first connection pad 311 will be formed. The first lower insulating layer 314u may be formed to fill the space where the first connection pad 311 will be formed.

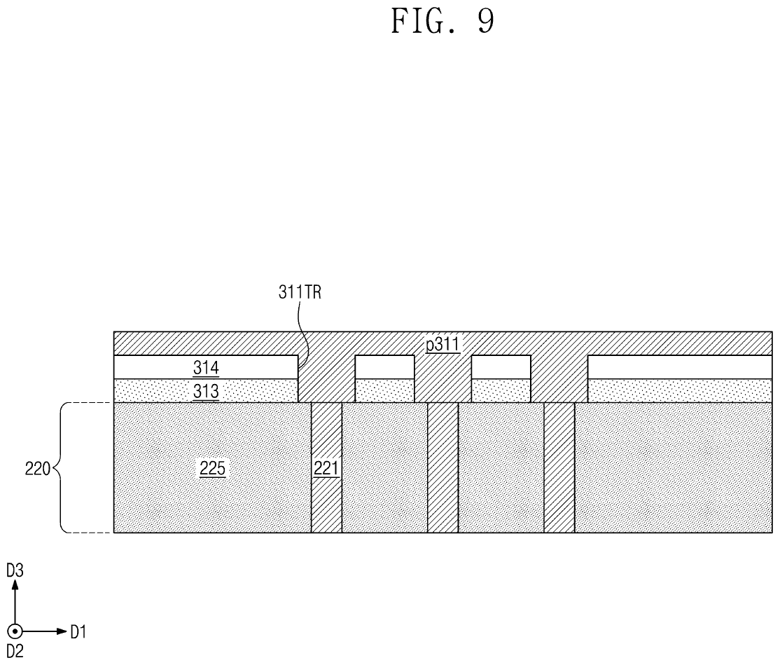

Referring to FIG. 9, the first lower insulating layer 314u may be removed. In an embodiment, the removing of the first lower insulating layer 314u may include, for example, oxide etching. Only the first lower insulating layer 314u may be removed, and the first insulating layer 314 may remain without being removed.

By removing the first lower insulating layer 314u, the space where the first connection pad 311 will be formed may be exposed again. The upper surface of the first penetration structure 221 and the portion of the upper surface of the first semiconductor substrate 225 may be exposed again. By removing the first lower insulating layer 314u, a pad trench 311TR may be formed. Side surfaces of the first heat conduction layer 313 and the first insulating layer 314 may be exposed by the pad trench 311TR.

In an embodiment, a preliminary pad pattern p311 may be formed to fill the pad trench 311TR. The preliminary pad pattern p311 may cover an upper surface of the first insulating layer 314 and side surfaces of the first heat conduction layer 313 and the first insulating layer 314. The preliminary pad pattern p311 may include a conductive material. In an embodiment, the preliminary pad pattern p311 may include, for example, copper.

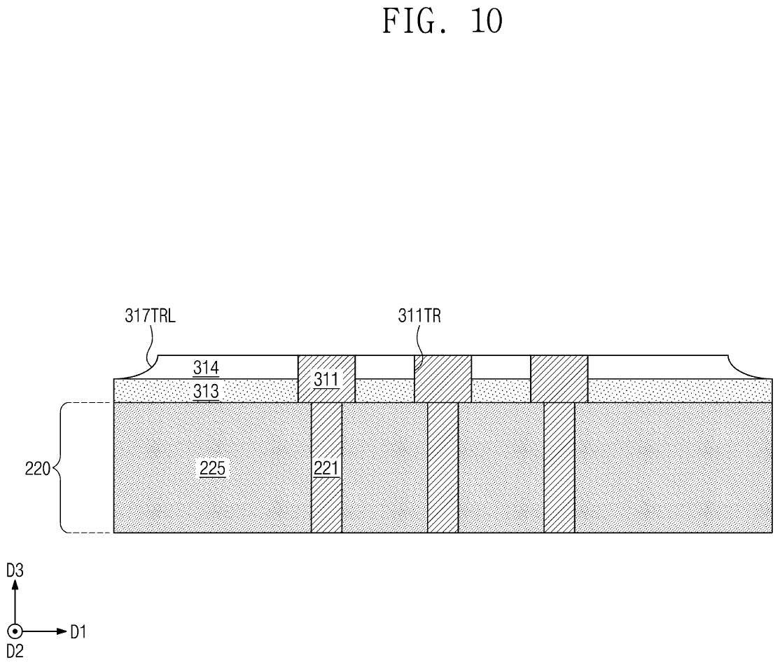

Referring to FIG. 10, an upper portion of the preliminary pad pattern p311 may be removed. In an embodiment, the removing of the upper portion of the preliminary pad pattern p311 may include a CMP process. The removing of the upper portion of the preliminary pad pattern p311 may include leaving the preliminary pad pattern p311 to fill the pad trench 311TR and removing the remaining preliminary pad pattern p311. A first connection pad 311 may be formed by the preliminary pad pattern p311 filling the pad trench 311TR after removing the upper portion of the preliminary pad pattern p311.

After the first connection pad 311 is formed, a portion of the first insulating layer 314 may be etched. A lower intervening trench 317TRL may be formed by etching a portion of the first insulating layer 314. In an embodiment, a plurality of lower intervening trenches 317TRL may be provided. The plurality of lower intervening trenches 317TRL may be formed by removing a portion of one side surface of the first insulating layer 314 and removing a portion of the other opposite side surface thereof. In an embodiment, the lower intervening trench 317TRL may include a curved curve. In an embodiment, the lower intervening trench 317TRL may include an inclined slope.

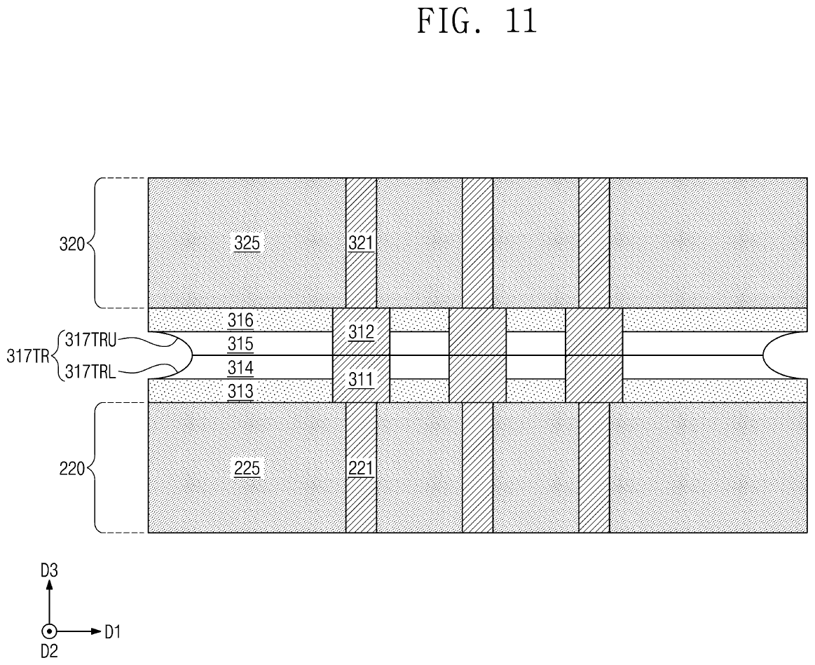

Referring to FIG. 11, similar to the method of FIGS. 5 to 10, a second heat conduction layer 316 and a second insulating layer 315 may be formed on the first semiconductor structure 220. A second connection pad 312 may be formed similarly to the first connection pad 311. An upper intervening trench 317TRU may be formed similarly to the lower intervening trench 317TRL. The upper intervening trench 317TRU and the lower intervening trench 317TRL may be bonded to each other, and the first insulating layer 314 and the second insulating layer 315 may be bonded to each other. For example, the upper intervening trench 317TRU may be in direct contact with the lower intervening trench 317TRL to form an intervening trench 317TR. The first connection pad 311 and the second connection pad 312 may be adhered to each other.

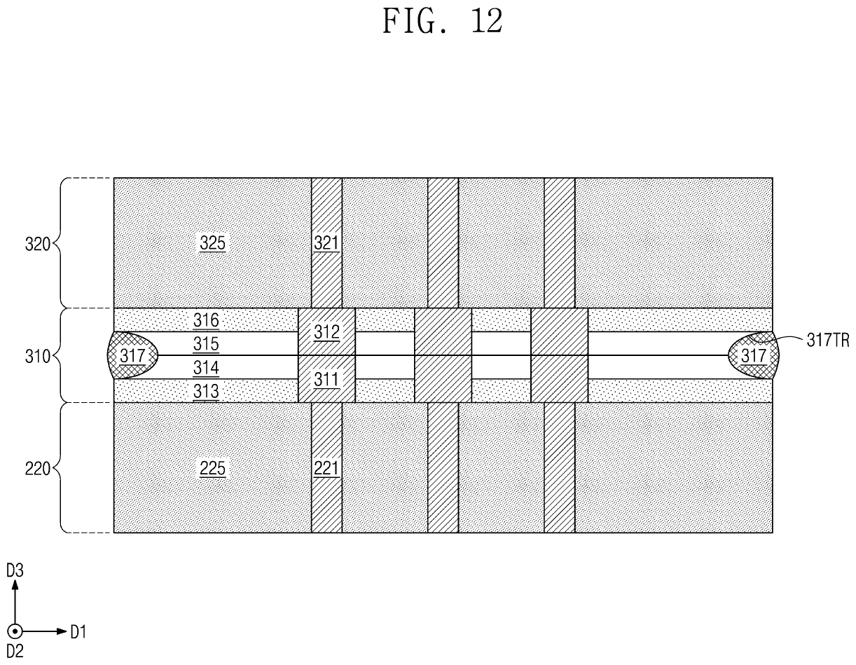

Referring to FIG. 12, a heat dissipation member 317 may be interposed to fill the intervening trench 317TR. The heat dissipation member 317 may be injected to fill the intervening trench 317TR, and in this embodiment, an exposed side surface of the heat dissipation member 317 may protrude slightly from a side surface of the first semiconductor substrate 225.

Referring again to FIGS. 1 and 2, a base connection structure 210, the first semiconductor structure 220, the first connection structure 310, and the second semiconductor structure 320 may be stacked on the base structure 100 (e.g., in the third direction D3). A second connection structure 410, a third semiconductor structure 420, a third connection structure 510, and a fourth semiconductor structure 520 may be stacked on the second semiconductor structure 320 (e.g., in the third direction D3). A solder layer 90 and a solder ball 81 may be connected below the base substrate 100. A molding layer 190 may be provided to cover an upper surface of base structure 100, a side surface of base connection structure 210, a side surface of first semiconductor structure 220, a side surface of first connection structure 310, a side surface of second semiconductor structure 320, a side surface of the second structure 410, a side surface of the third semiconductor structure 420, a side surface of the third connection structure 510, and a side surface and an upper surface of the fourth structure 520. Accordingly, the semiconductor package 1 of FIG. 1 may be formed.

In the semiconductor package and the method of manufacturing the same according to an embodiment of the present inventive concept, the heat dissipation member may be inserted between the plurality of semiconductor chips when stacking the semiconductor chips, thereby increasing the heat dissipation characteristics.

In the semiconductor package and the method of manufacturing the same according to an embodiment of the present inventive concept, the heat dissipation member may be inserted between the plurality of semiconductor chips when stacking the semiconductor chips, thereby reducing the warpage.

While embodiments of the present inventive concept are described above, a person skilled in the art may understand that many modifications and variations are made without departing from the spirit and scope of the present inventive concept. Accordingly, the described embodiments of the present inventive concept should be considered in all respects as illustrative and not restrictive, with the spirit and scope of the present inventive concept.

What is claimed is:

1. A semiconductor package comprising:
a first semiconductor structure including a first semiconductor substrate and a first penetration structure penetrating the first semiconductor substrate;
a connection structure disposed on the first semiconductor structure; and
a second semiconductor structure disposed on the connection structure, the second semiconductor structure including a second semiconductor substrate and a second penetration structure penetrating the second semiconductor substrate,
wherein the connection structure includes:
a first heat conduction layer disposed on the first semiconductor substrate;
a first insulating layer disposed on the first heat conduction layer;
a second insulating layer disposed on the first insulating layer;
a second heat conduction layer disposed on the second insulating layer; and
a heat dissipation member interposed between the first insulating layer and the second insulating layer, and
wherein the first heat conduction layer and the first insulating layer include different materials from each other.

2. The semiconductor package of claim 1, wherein an outer surface of the heat dissipation member directly contacts a molding layer, the outer surface of the heat dissipation member including a curved surface.

3. The semiconductor package of claim 1, wherein the first heat conduction layer includes aluminum nitride or boron nitride.

4. The semiconductor package of claim 1, wherein the heat dissipation member includes at least one material selected from epoxy, silicone, urethane, acrylates, aluminum oxide, boron nitride, zinc oxide and aluminum nitride.

5. The semiconductor package of claim 1, wherein the first heat conduction layer has a thickness in a range of about 0.1 um to about 3 um.

6. The semiconductor package of claim 1, further comprising a molding layer surrounding side surfaces of the first semiconductor structure, the connection structure, and the second semiconductor structure,
wherein an outer surface of the heat dissipation member directly contacts the molding layer, the outer surface of the heat dissipation member including a curved surface, and
wherein a first inner surface of the heat dissipation member directly contacts the first insulating layer, the first inner surface including an inclined surface.

7. The semiconductor package of claim 1, wherein the connection structure includes:
a first connection pad penetrating the first heat conduction layer and the first insulating layer; and
a second connection pad penetrating the second heat conduction layer and the second insulating layer,
wherein the first penetration structure, the first connection pad, the second connection pad, and the second penetration structure are electrically connected to each other.

8. The semiconductor package of claim 7, wherein:
the first insulating layer includes silicon oxide; and
the first connection pad and the second connection pad include copper.

9. The semiconductor package of claim 1, further comprising a molding layer surrounding the first semiconductor structure, the connection structure, and the second semiconductor structure,
wherein an outer surface of the heat dissipation member directly contacts the molding layer, the outer surface of the heat dissipation member protruding towards the molding layer.

10. A semiconductor package comprising:
a first semiconductor structure including a first semiconductor substrate and a first penetration structure penetrating the first semiconductor substrate;
a connection structure disposed on the first semiconductor structure;
a second semiconductor structure disposed on the connection structure, the second semiconductor structure including a second semiconductor substrate and a second penetration structure penetrating the second semiconductor substrate; and
a molding layer disposed on the first semiconductor structure, the connecting structure, and the second penetration structure,
wherein the connection structure includes:
a first heat conduction layer disposed on the first semiconductor substrate;
a first insulating layer disposed on the first heat conduction layer;
a second insulating layer disposed on the first insulating layer;
a second heat conduction layer disposed on the second insulating layer; and
a heat dissipation member interposed between the first insulating layer and the second insulating layer, and
wherein an outer surface of the heat dissipation member protrudes towards the molding layer.

11. The semiconductor package of claim 10, wherein:
the outer surface of the heat dissipation member includes a curved surface;
an inner surface of the heat dissipation member includes a curved surface,
wherein a curvature of the inner surface of the heat dissipation member is greater than a curvature of the outer surface of the heat dissipation member.

12. The semiconductor package of claim 10, wherein the heat dissipation member includes a step portion having a staircase shape at a portion directly contacting the first insulating layer.

13. The semiconductor package of claim 10, wherein the heat dissipation member includes at least one material selected from epoxy, silicone, urethane, acrylate, aluminum oxide, boron nitride, zinc oxide and aluminum nitride.

14. The semiconductor package of claim 10, wherein:
the outer surface of the heat dissipation member includes a curved surface; and
each of a first inner surface of the heat dissipation member that directly contacts the first insulating layer and a second inner surface of the heat dissipation member that directly contacts the second insulating layer includes an inclined surface.

15. The semiconductor package of claim 10, wherein the heat dissipation member is disposed in an intervening trench that is defined in the first insulating layer and the second insulating layer.

16. The semiconductor package of claim 10, wherein the connection structure includes:
a first connection pad penetrating the first heat conduction layer and the first insulating layer; and
a second connection pad penetrating the second heat conduction layer and the second insulating layer,
wherein the first penetration structure, the first connection pad, the second connection pad, and the second penetration structure are electrically connected to each other.

17. A semiconductor package comprising:
a first semiconductor structure including a first semiconductor substrate and a first penetration structure penetrating the first semiconductor substrate;
a connection structure disposed on the first semiconductor structure;
a second semiconductor structure disposed on the connection structure, the second semiconductor structure including a second semiconductor substrate and a second penetration structure penetrating the second semiconductor substrate; and
a molding layer disposed on the first semiconductor structure, the connecting structure, and the second penetration structure,
wherein the connection structure includes:
a first heat conduction layer disposed on the first semiconductor substrate;
a first insulating layer disposed on the first heat conduction layer;
a second insulating layer disposed on the first insulating layer;
a second heat conduction layer disposed on the second insulating layer; and
a heat dissipation member interposed between the first insulating layer and the second insulating layer,
wherein an outer surface of the heat dissipation member protrudes towards the molding layer,
wherein the heat dissipation member includes at least one material selected from epoxy, silicone, urethane, acrylate, aluminum oxide, boron nitride, zinc oxide, and aluminum nitride, and
wherein a thermal conductivity of the first heat conduction layer is greater than a thermal conductivity of the first insulating layer.

18. The semiconductor package of claim 17, wherein the heat dissipation member is disposed in an intervening trench that is defined in the first insulating layer and the second insulating layer.

19. The semiconductor package of claim 17, wherein the heat dissipation member includes a step portion having a staircase shape directly contacting the first heat conduction layer and the first insulating layer.

20. The semiconductor package of claim 17, wherein:
the outer surface of the heat dissipation member includes a curved surface,
an inner surface of the heat dissipation member includes a curved surface; and
a curvature of the outer surface is less than a curvature of the inner surface.
